(19) United States
(12) Patent Application Publication
(10) Pub. No.: US 2025/0118498 A1
(43) Pub. Date: Apr. 10, 2025

(54) MULTILAYER CERAMIC CAPACITOR, PACKAGE, AND CIRCUIT BOARD

(71) Applicant: TAIYO YUDEN CO., LTD., Tokyo (JP)

(72) Inventor: Ayumi SHIROTA, Tokyo (JP)

(73) Assignee: TAIYO YUDEN CO., LTD., Tokyo (JP)

(21) Appl. No.: 18/983,271

(22) Filed: Dec. 16, 2024

Related U.S. Application Data
(63) Continuation of application No. PCT/JP2023/024761, filed on Jul. 4, 2023.

(30) Foreign Application Priority Data
Jul. 7, 2022 (JP) 2022-109466

(51) Int. Cl. H01G 4/30; H01G 4/008; H01G 4/012; H01G 4/232; H05K 1/18

(52) U.S. Cl. CPC H01G 4/30; H01G 4/0085; H01G 4/012; H01G 4/2325; H05K 1/181; H05K 2201/10015

(57) ABSTRACT

A multilayer ceramic capacitor has a dimension in a first axis direction equal to or greater than 1.5 times a dimension in a second axis direction, and includes a ceramic body and a pair of external electrodes. The external electrodes contain Cu as a main component and cover respective end surfaces. The ceramic body includes a multilayer portion including internal electrodes that contain Ni as a main component, are alternately stacked with ceramic layers along a stacking direction, and are led out to connection ends on the end surfaces, and a pair of margin portions that cover the multilayer portion from a width direction of the internal electrodes, and contain a low-melting-point metal having a lower melting point than Ni. In each of the internal electrodes, a width dimension at the connection end is smaller than at a center in a third axis direction.

### CROSS-REFERENCE TO RELATED APPLICATION

This application is a continuation application of PCT/JP2023/024761 filed on Jul. 4, 2023, which claims priority to Japanese Patent Application No. 2022-109466 filed on Jul. 7, 2022, the entire contents of which are incorporated herein by reference.

### FIELD

A certain aspect of the present disclosure relates to a multilayer ceramic capacitor, a package, and a circuit board.

### BACKGROUND

Japanese Patent Application Laid-Open No. 2012-209539 (Patent Document 1) discloses a technique of forming a green chip having a structure in which internal electrodes are exposed on side surfaces, and attaching ceramic green sheets for side surfaces to the respective side surfaces to form ceramic protective layers. In such a technique, the ceramic protective layer can be formed to be thin, but the reliability of the ceramic protective layer is an issue. For example, Japanese Patent Application Publication No. 2021-034648 (Patent Document 2) discloses a technique of adding Sn to an internal electrode paste containing Ni to form a barrier portion containing Ni and Sn between an internal electrode layer and a side margin, thereby improving insulation properties.

On the other hand, International Publication No. 2014/175034 (Patent Document 3) describes a phenomenon in which, when an external electrode containing Cu as a main component is fired on a ceramic body including internal electrodes containing Ni as a main component, Cu in the external electrode diffuses into the internal electrodes while reacting with Ni. This phenomenon causes expansion of the end portions adjacent to the external electrode of the internal electrodes in the ceramic body.

In the ceramic body, only the section adjacent to the external electrode tends to expand in the stacking direction due to the expansion of the internal electrodes. In the ceramic body, internal stress generated by the expansion concentrates on the corner portions, and thus cracks are likely to be generated. Such cracks are more likely to be generated in a tall structure having a large number of internal electrodes stacked.

### SUMMARY

Furthermore, when a metal having a lower melting point than Ni, such as Sn, is added to the ceramic body in order to improve the insulation properties, the amount of Cu diffused from the external electrodes is further increased, and thus, cracks are more likely to be generated.

In view of the above circumstances, it is an object of the present disclosure to provide a multilayer ceramic capacitor, a package, and a circuit board that are capable of improving insulation properties and inhibiting the generation of cracks in a ceramic body in a tall structure.

A multilayer ceramic capacitor according to one embodiment of the present disclosure has a dimension in a first direction along a first axis equal to or greater than 1.5 times a dimension in a second direction along a second axis orthogonal to the first axis, and is to be mounted on a mounting surface perpendicular to the first axis.

The multilayer ceramic capacitor includes a ceramic body and a pair of external electrodes.

The ceramic body has a pair of main surfaces perpendicular to the first axis, a pair of side surfaces perpendicular to the second axis, and a pair of end surfaces perpendicular to a third axis orthogonal to the first axis and the second axis.

The pair of external electrodes contain Cu as a main component and cover the pair of end surfaces, respectively.

The ceramic body further includes:
a multilayer portion including a plurality of internal electrodes that contain Ni as a main component, are alternately stacked with ceramic layers along a stacking direction parallel to the first axis or the second axis, and are led out to connection ends on the end surfaces, respectively, and
a pair of margin portions that are formed along the stacking direction, cover the multilayer portion from a width direction of the internal electrodes, and contain a low-melting-point metal having a melting point lower than that of Ni, the width direction being orthogonal to the stacking direction and the third axis.

In each of the internal electrodes, a width dimension in the width direction is smaller at the connection end than at a center in a third direction along the third axis.

A multilayer ceramic capacitor according to another embodiment of the present disclosure has a dimension in a first direction along a first axis equal to or greater than 1.3 times a dimension in a second direction along a second axis orthogonal to the first axis, and is to be mounted on a mounting surface perpendicular to the first axis.

The multilayer ceramic capacitor includes a ceramic body and a pair of external electrodes.

The ceramic body has a pair of main surfaces perpendicular to the first axis, a pair of side surfaces perpendicular to the second axis, and a pair of end surfaces perpendicular to a third axis orthogonal to the first axis and the second axis.

The pair of external electrodes contain Cu as a main component and cover the pair of end surfaces, respectively.

The ceramic body further includes:
a multilayer portion including a plurality of internal electrodes that contain Ni as a main component, are alternately stacked with ceramic layers along a stacking direction parallel to the first axis or the second axis, and are led out to connection ends on the end surfaces, respectively, and
a pair of margin portions that are formed along the stacking direction, cover the multilayer portion from a width direction of the internal electrodes, and contain a low-melting-point metal having a melting point lower than that of Ni, the width direction being orthogonal to the stacking direction and the third axis.

In each of the internal electrodes, a width dimension in the width direction is smaller at the connection end than at a center in a third direction along the third axis.

In the above configuration, the connection ends are separated from the margin portions, and thus the influence of the low-melting-point metal on the connection ends is reduced. This reduces an increase in the amount of Cu diffused from the external electrodes, which may be caused by the low-melting-point metal during the firing of the external electrodes. Therefore, in the above-described configuration, it is possible to inhibit generation of cracks in the ceramic body due to expansion near the connection ends while increasing the insulation properties of the margin portions by the low-melting-point metal.

For example, the low-melting-point metal may be at least one of the following metals: Sn, Zn, Al, Ga, Ge, and Ag.

For example, the width dimension at the connection end may be equal to or greater than ½ of and equal to or less than ¾ of the width dimension at the center. This makes it possible to ensure a sufficient width dimension of the connection end while ensuring a sufficient distance between the connection end and the margin portion, and to stably connect the connection end to the external electrode.

For example, the stacking direction may be parallel to the second axis, and the width direction of the internal electrodes may be parallel to the first axis.

In this case, the main surfaces may have a higher flatness than the side surfaces.

A package according to another embodiment of the present disclosure includes a multilayer ceramic capacitor, a carrier tape, and a top tape.

The multilayer ceramic capacitor has a dimension in a first direction along a first axis equal to or greater than 1.5 times a dimension in a second direction along a second axis orthogonal to the first axis, and is to be mounted on a mounting surface perpendicular to the first axis.

The multilayer ceramic capacitor includes a ceramic body and a pair of external electrodes.

The ceramic body has a pair of main surfaces perpendicular to the first axis, a pair of side surfaces perpendicular to the second axis, and a pair of end surfaces perpendicular to a third axis orthogonal to the first axis and the second axis.

The pair of external electrodes contain Cu as a main component and cover the pair of end surfaces, respectively.

The ceramic body further includes:
a multilayer portion including a plurality of internal electrodes that contain Ni as a main component, are alternately stacked with ceramic layers along a stacking direction parallel to the first axis or the second axis, and are led out to connection ends on the end surfaces, respectively, and
a pair of margin portions that are formed along the stacking direction, cover the multilayer portion from a width direction of the internal electrodes, and contain a low-melting-point metal having a melting point lower than that of Ni, the width direction being orthogonal to the stacking direction and the third axis.

In each of the internal electrodes, a width dimension in the width direction is smaller at the connection end than at a center in a third direction along the third axis.

The carrier tape has a sealing surface perpendicular to the first axis, and a recess that is recessed from the sealing surface in the first direction and accommodates the multilayer ceramic capacitor.

The top tape is attached to the sealing surface and covers the recess.

A package according to another embodiment of the present disclosure includes a multilayer ceramic capacitor, a carrier tape, and a top tape.

The multilayer ceramic capacitor has a dimension in a first direction along a first axis equal to or greater than 1.3 times a dimension in a second direction along a second axis orthogonal to the first axis, and is to be mounted on a mounting surface perpendicular to the first axis.

The multilayer ceramic capacitor includes a ceramic body and a pair of external electrodes.

The ceramic body has a pair of main surfaces perpendicular to the first axis, a pair of side surfaces perpendicular to the second axis, and a pair of end surfaces perpendicular to a third axis orthogonal to the first axis and the second axis.

The pair of external electrodes contain Cu as a main component and cover the pair of end surfaces.

The ceramic body further includes:
a multilayer portion including a plurality of internal electrodes that contain Ni as a main component, are alternately stacked with ceramic layers along a stacking direction parallel to the first axis or the second axis, and are led out to connection ends on the end surfaces, respectively, and
a pair of margin portions that are formed along the stacking direction, cover the multilayer portion from a width direction of the internal electrodes, and contain a low-melting-point metal having a melting point lower than that of Ni, the width direction being orthogonal to the stacking direction and the third axis.

In each of the internal electrodes, a width dimension in the width direction is smaller at the connection end than at a center in a third direction along the third axis.

The carrier tape has a sealing surface perpendicular to the first axis, and a recess that is recessed from the sealing surface in the first direction and accommodates the multilayer ceramic capacitor.

The top tape is attached to the sealing surface and covers the recess.

A circuit board according to another embodiment of the present disclosure includes a multilayer ceramic capacitor and a mounting substrate.

The multilayer ceramic capacitor has a dimension in a first direction along a first axis equal to or greater than 1.5 times a dimension in a second direction along a second axis orthogonal to the first axis, and is to be mounted on a mounting surface perpendicular to the first axis.

The multilayer ceramic capacitor includes a ceramic body and a pair of external electrodes.

The ceramic body has a pair of main surfaces perpendicular to the first axis, a pair of side surfaces perpendicular to the second axis, and a pair of end surfaces perpendicular to a third axis orthogonal to the first axis and the second axis.

The pair of external electrodes contain Cu as a main component and cover the pair of end surfaces, respectively.

The ceramic body further includes:
a multilayer portion including a plurality of internal electrodes that contain Ni as a main component, are alternately stacked with ceramic layers along a stacking direction parallel to the first axis or the second axis, and are led out to connection ends on the end surfaces, respectively, and
a pair of margin portions that are formed along the stacking direction, cover the multilayer portion from a width direction of the internal electrodes, and contain a low-melting-point metal having a melting point lower than that of Ni, the width direction being orthogonal to the stacking direction and the third axis.

In each of the internal electrodes, a width dimension in the width direction is smaller at the connection end than at a center in a third direction along the third axis.

The mounting substrate has a mounting surface perpendicular to the first axis, and a pair of connection electrodes provided on the mounting surface and connected to the pair of external electrodes of the multilayer ceramic capacitor through solder, respectively.

A circuit board according to another embodiment of the present disclosure includes a multilayer ceramic capacitor and a mounting substrate.

The multilayer ceramic capacitor has a dimension in a first direction along a first axis equal to or greater than 1.3 times a dimension in a second direction along a second axis orthogonal to the first axis, and is to be mounted on a mounting surface perpendicular to the first axis.

The multilayer ceramic capacitor includes a ceramic body and a pair of external electrodes.

The ceramic body has a pair of main surfaces perpendicular to the first axis, a pair of side surfaces perpendicular to the second axis, and a pair of end surfaces perpendicular to a third axis orthogonal to the first axis and the second axis.

The pair of external electrodes contain Cu as a main component and cover the pair of end surfaces, respectively.

The ceramic body further includes:
a multilayer portion including a plurality of internal electrodes that contain Ni as a main component, are alternately stacked with ceramic layers along a stacking direction parallel to the first axis or the second axis, and are led out to connection ends on the end surfaces, respectively, and
a pair of margin portions that are formed along the stacking direction, cover the multilayer portion from a width direction of the internal electrodes, and contain a low-melting-point metal having a melting point lower than that of Ni, the width direction being orthogonal to the stacking direction and the third axis.

In each of the internal electrodes, a width dimension in the width direction is smaller at the connection end than at a center in a third direction along the third axis.

The mounting substrate has a mounting surface perpendicular to the first axis, and a pair of connection electrodes provided on the mounting surface and connected to the pair of external electrodes of the multilayer ceramic capacitor through solder, respectively.

### BRIEF DESCRIPTION OF THE DRAWINGS

FIG. 1 is a perspective view of a multilayer ceramic capacitor according to a first embodiment;

FIG. 2 is a cross-sectional view of the multilayer ceramic capacitor taken along line A1-A1′ in FIG. 1;

FIG. 3 is a cross-sectional view of the multilayer ceramic capacitor taken along line B1-B1′ in FIG. 1;

FIG. 4 is an exploded view partially illustrating the ceramic body of the multilayer ceramic capacitor;

FIG. 5 is a cross-sectional view of the multilayer ceramic capacitor taken along line A2-A2′ in FIG. 1;

FIG. 6 is a cross-sectional view of the multilayer ceramic capacitor taken along line B2-B2′ in FIG. 1;

FIG. 7 is a flowchart illustrating a method of manufacturing the multilayer ceramic capacitor;

FIG. 8A, FIG. 8B, and FIG. 8C are plan views of ceramic sheets prepared in step S01, respectively;

FIG. 9 schematically illustrates step S02;

FIG. 10 is a plan view illustrating step S03;

FIG. 11 and FIG. 11B are cross-sectional views illustrating step S04;

FIG. 12 is a side view of a circuit board including the multilayer ceramic capacitor;

FIG. 13 is a partial plan view of a package of the multilayer ceramic capacitor;

FIG. 14 is a cross-sectional view of the package taken along line C-C′ in FIG. 15;

FIG. 15 is a cross-sectional view of a multilayer ceramic capacitor according to a second embodiment, taken along line B1-B1′ in FIG. 1;

FIG. 16 is a cross-sectional view of the multilayer ceramic capacitor taken along line D1-D1′ in FIG. 1;

FIG. 17 is an exploded view partially illustrating the ceramic body of the multilayer ceramic capacitor;

FIG. 18 is a cross-sectional view of the multilayer ceramic capacitor taken along line B2-B2′ in FIG. 1;

FIG. 19 is a cross-sectional view of the multilayer ceramic capacitor taken along the line D2-D2′ in FIG. 1;

FIG. 20A, FIG. 20B, and FIG. 20C are plan views of ceramic sheets prepared in step S01 of the method of manufacturing the multilayer ceramic capacitor, respectively;

FIG. 21 schematically illustrates step S02 of the method of manufacturing the multilayer ceramic capacitor; and

FIG. 22A and FIG. 22B are partial cross-sectional views illustrating a method of calculating the flatness of the main surface and the flatness of the side surface of the multilayer ceramic capacitor, FIG. 22A illustrates a cross section of the center of the main surface, and FIG. 22B illustrates a cross section of the center of the side surface.

### DETAILED DESCRIPTION

Hereinafter, a multilayer ceramic capacitor 10 according to an embodiment of the present disclosure will be described with reference to the drawings. In the drawings, an X-axis, a Y-axis, and a Z-axis orthogonal to each other are illustrated as appropriate. The X-axis, the Y-axis, and the Z-axis define a fixed coordinate system fixed with respect to the multilayer ceramic capacitor 10.

### First Embodiment

### [Structure of Multilayer Ceramic Capacitor 10]

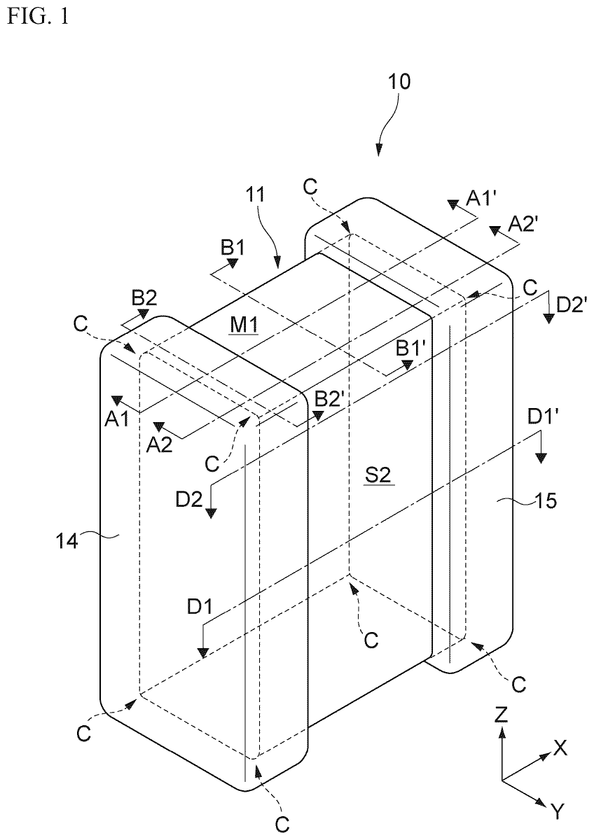

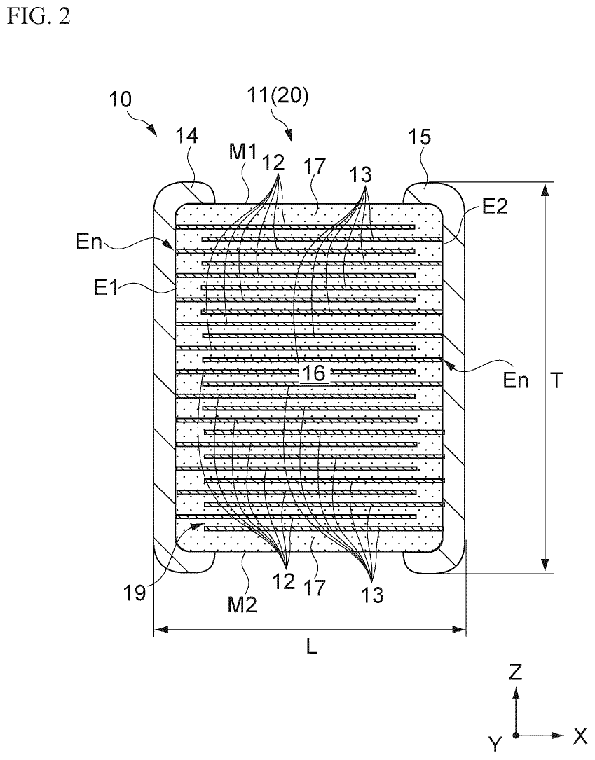

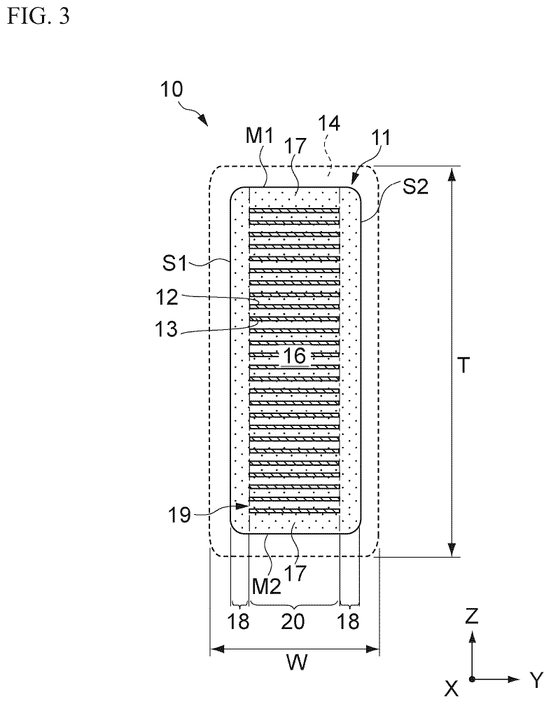

FIG. 1 to FIG. 3 illustrate the multilayer ceramic capacitor 10 according to a first embodiment of the present disclosure. FIG. 1 is a perspective view of the multilayer ceramic capacitor 10. FIG. 2 is a cross-sectional view of the multilayer ceramic capacitor 10 taken along line A1-A1′ in FIG. 1. FIG. 3 is a cross-sectional view of the multilayer ceramic capacitor 10 taken along line B1-B1′ in FIG. 1.

FIG. 1 and FIG. 2 illustrate vertical cross sections of a section including the central portion of the multilayer ceramic capacitor 10. Specifically, FIG. 2 illustrates a cross section of the multilayer ceramic capacitor 10 along the X-Z plane at the center in the Y-axis direction. FIG. 3 illustrates a cross section of the multilayer ceramic capacitor 10 along the Y-Z plane at the center in the X-axis direction.

The multilayer ceramic capacitor 10 includes a ceramic body 11, a first external electrode 14, and a second external electrode 15. The ceramic body 11 is configured as a hexahedron having first and second main surfaces M1 and M2 orthogonal to the Z-axis, first and second end surfaces E1 and E2 orthogonal to the X-axis, and first and second side surfaces S1 and S2 orthogonal to the Y-axis. The “hexahedron” may be substantially hexahedral, and for example, the ridge portions connecting the surfaces of the ceramic body 11 may be rounded.

The main surfaces M1 and M2, the end surfaces E1 and E2, and the side surfaces S1 and S2 of the ceramic body 11 are all flat surfaces. The flat surface in the present embodiment does not have to be strictly flat as long as it is a surface recognized as flat when viewed as a whole, and includes, for example, a surface having minute surface irregularities, a surface having a gently curved shape existing in a predetermined area, and the like.

The multilayer ceramic capacitor 10 is a tall type in which the dimension T in the Z-axis direction is equal to or greater than 1.5 times the dimension W in the Y-axis direction. In the multilayer ceramic capacitor 10, the capacitance is increased by increasing the dimension T corresponding to the height. Thus, the multilayer ceramic capacitor 10 can be mounted in a mounting space limited in the Y-axis direction.

The multilayer ceramic capacitor 10 may be a tall type in which the dimension T in the Z-axis direction is equal to or greater than 1.3 times the dimension W in the Y-axis direction.

In the multilayer ceramic capacitor 10, the dimension L of the ceramic body 11 in the X-axis direction may be smaller than the dimension T as long as it is larger than the dimension W. In the multilayer ceramic capacitor 10, the dimensions T, W, and L of the ceramic body 11 can be determined as desired within respective ranges satisfying the above conditions.

Specifically, in the multilayer ceramic capacitor 10, for example, the dimension L can be 0.2 mm or greater and 1.2 mm or less, the dimension W can be 0.1 mm or greater and 0.7 mm or less, and the dimension T can be 0.15 mm or greater and 1.0 mm or less. The dimensions T, W, and L are all the maximum dimensions of the multilayer ceramic capacitor 10 in respective directions.

In the following description, “inner side in the Z-axis direction” refers to a side closer to a virtual X-Y plane that bisects the multilayer ceramic capacitor 10 in the Z-axis direction, and “outer side in the Z-axis direction” refers to a side farther from the virtual X-Y plane. Similarly, the “inner side in the Y-axis direction” refers to a side closer to a virtual X-Z plane that bisects the multilayer ceramic capacitor 10 in the Y-axis direction, and the “outer side in the Y-axis direction” refers to a side farther from the virtual X-Z plane.

The first and second external electrodes 14 and 15 extend inward in the X-axis direction from the end surfaces E1 and E2 of the ceramic body 11, respectively, along the main surfaces M1 and M2 and the side surfaces S1 and S2, and are separated from each other on the main surfaces M1 and M2 and the side surfaces S1 and S2. As a result, in both external electrodes 14 and 15, the cross sections along the X-Y and X-Z planes are U-shaped.

The external electrodes 14 and 15 are each formed of copper (Cu) as a main component. In the present embodiment, the main component refers to a component having the highest content ratio.

The ceramic body 11 includes a multilayer portion 20 and a pair of margin portions 18. The multilayer portion 20 includes a capacitance formation portion 16 and a pair of cover portions 17. The capacitance formation portion 16 includes a plurality of first and second internal electrodes 12 and 13 that are alternately stacked with a plurality of ceramic layers 19 along the Z-axis direction. In the present embodiment, the internal electrodes 12 and 13 and the ceramic layers 19 are each configured in a sheet shape extending along the X-Y plane.

The internal electrodes 12 and 13 are each formed of nickel (Ni) as a main component. The internal electrodes 12 and 13 face each other in the Z-axis direction in an opposing section that is located in the center in the X-axis and Y-axis directions. The first internal electrodes 12 are led out from the opposing section to respective connection ends En on the first end surface E1 and are connected to the first external electrode 14 at the connection ends En. The second internal electrodes 13 are led out from the opposing section to respective connection ends En on the second end surface E2 and are connected to the second external electrode 15 at the connection ends En on the second end surface E2.

With such a configuration, in the multilayer ceramic capacitor 10, when a voltage is applied between the external electrodes 14 and 15, a voltage is applied to the ceramic layers 19 between the internal electrodes 12 and 13 in the opposing section. This allows the multilayer ceramic capacitor 10 to store an electric charge corresponding to the voltage between the external electrodes 14 and 15.

Here, the direction in which the internal electrodes 12 and 13 are stacked is defined as a “stacking direction”, the direction in which the internal electrodes 12 and 13 are led out is defined as a “lead-out direction”, and the direction orthogonal to the stacking direction and the lead-out direction is defined as a “width direction (of the internal electrodes 12 and 13)”. In the present embodiment, the stacking direction is a direction parallel to the Z-axis, the lead-out direction is a direction parallel to the X-axis, and the width direction is a direction parallel to the Y-axis.

In the multilayer portion 20, a dielectric ceramic having a high dielectric constant is used to increase the capacitance of each ceramic layer 19 between the internal electrodes 12 and 13. Examples of the dielectric ceramic having a high dielectric constant include a material having a perovskite structure containing barium (Ba) and titanium (Ti), which is represented by barium titanate (BaTiO₃).

The dielectric ceramic may be a composition system such as strontium titanate (SrTiO₃), calcium titanate (CaTiO₃), magnesium titanate (MgTiO₃), calcium zirconate (CaZrO₃), calcium zirconate titanate (Ca(Zr, Ti)O₃), barium calcium zirconate titanate ((Ba, Ca)(Zr, Ti)O₃), barium zirconate (BaZrO₃), or titanium dioxide (TiO₂).

The pair of cover portions 17 cover the capacitance formation portion 16 from respective sides in the Z-axis direction, which is the stacking direction. The cover portion 17 is formed of, for example, a layered product of ceramic sheets extending along the X-Y plane. The dielectric ceramic constituting the cover portion 17 preferably has the same composition as the ceramic layer 19 to reduce internal stress.

The pair of margin portions 18 are formed along the Z-axis direction and cover the multilayer portion 20 from the Y-axis direction. The margin portions 18 are attached to respective surfaces perpendicular to the Y-axis of the multilayer portion 20 as described later. For example, the margin portion 18 is formed of a ceramic sheet and is configured in a sheet shape extending along the X-Z plane. The dielectric ceramic constituting the margin portion 18 preferably has the same composition as the ceramic layer 19 to reduce internal stress.

Furthermore, to enhance insulating properties, the margin portion 18 includes a low-melting-point metal having a melting point lower than that of Ni, which is the main component of the internal electrodes 12 and 13. The low-melting-point metal is, for example, at least one of the following metals: tin (Sn), zinc (Zn), aluminum (Al), gallium (Ga), germanium (Ge), and silver (Ag), and is preferably, for example, Sn. The margin portion 18 may contain one kind of low-melting-point metal or may contain a plurality of kinds of low-melting-point metals. The ceramic layers 19 of the multilayer portion 20 may contain a low-melting-point metal at a concentration lower than that of the margin portion 18, but preferably do not contain a low-melting-point metal.

In the multilayer ceramic capacitor 10, the external electrodes 14 and 15 formed of Cu as a main component and the connection ends En of the internal electrodes 12 and 13 formed of Ni as a main component are connected to each other on the end surfaces E1 and E2 of the ceramic body 11, respectively. The external electrodes 14 and 15 are configured as fired films that are fired on the ceramic body 11.

When the external electrodes 14 and 15 are fired on the ceramic body 11, Cu in the external electrodes 14 and 15 diffuses into the internal electrodes 12 and 13 from the connection ends En while reacting with Ni constituting the internal electrodes 12 and 13. That is, in the internal electrodes 12 and 13, Ni constituting the end portions in the X-axis direction including the connection ends En react with Cu to form a copper-nickel alloy. Furthermore, when the low-melting-point metal is distributed near the connection ends En, the diffusion of Cu in the internal electrodes 12 and 13 is further promoted.

In the internal electrodes 12 and 13, the end portions in the X-axis direction including the connection ends En expand in the stacking direction parallel to the Z-axis due to the diffusion of Cu. Therefore, in the ceramic body 11, both end portions of the internal electrodes 12 and 13 in the X-axis direction, where the internal electrodes 12 and 13 expand, tend to expand in the stacking direction along the Z-axis, and thus internal stress is generated.

In general, in the ceramic body 11, internal stress caused by expansion of both end portions in the X-axis direction tends to concentrate on corner portions C. Here, the corner portions C of the ceramic body 11 refer to eight portions that connect three surfaces, i.e., one of the main surfaces M1 and M2, one of the end surfaces E1 and E2, and one of the side surfaces S1 and S2, to each other, as illustrated in FIG. 1.

In the ceramic body 11, as the number of stacked internal electrodes 12 and 13 increases, the expansion force caused by the expansion of each internal electrode 12, 13 is amplified, and thus the internal stress concentrated on the corner portion C increases. In the ceramic body 11, as the internal stress concentrated on the corner portion C increases, a crack is more likely to be generated in the corner portion C.

In the multilayer ceramic capacitor 10, when a crack is generated in the corner portion C of the ceramic body 11, the crack serves as a path through which moisture enters, and thus the moisture resistance is likely to be reduced. In addition, in the ceramic body 11, the corner portion C is covered with the external electrode 14 or 15, and thus it is difficult to find a crack generated in the corner portion C by visual inspection.

In contrast, in the multilayer ceramic capacitor 10 according to the present embodiment, the internal electrodes 12 and 13 are configured to effectively reduce the concentration of internal stress on the corner portions C of the ceramic body 11 due to the diffusion of Cu contained in the external electrodes 14 and 15 into the internal electrodes 12 and 13. The internal electrodes 12 and 13 will be described in detail below.

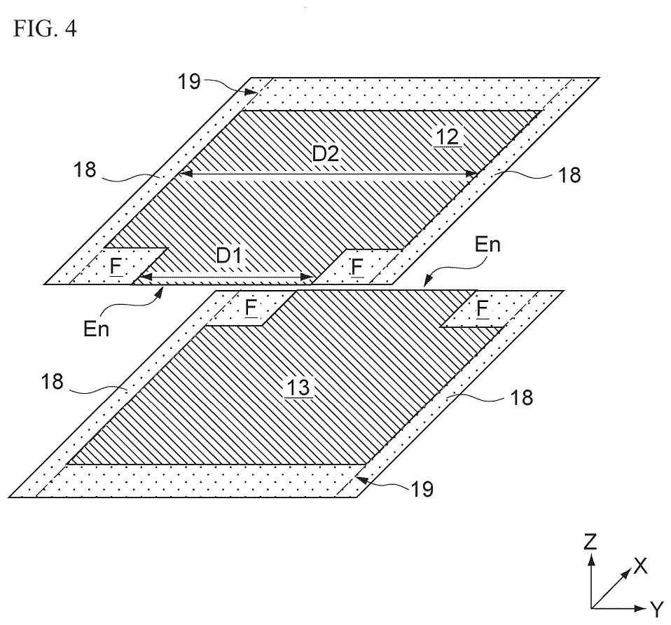

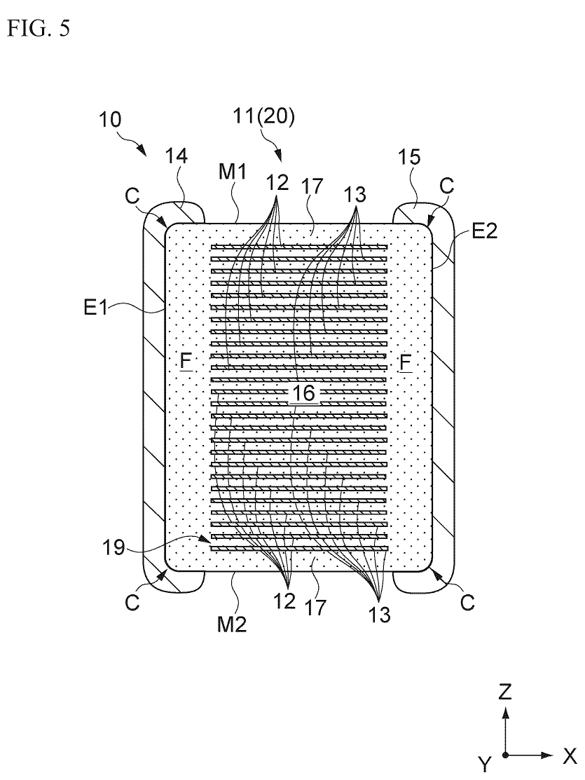

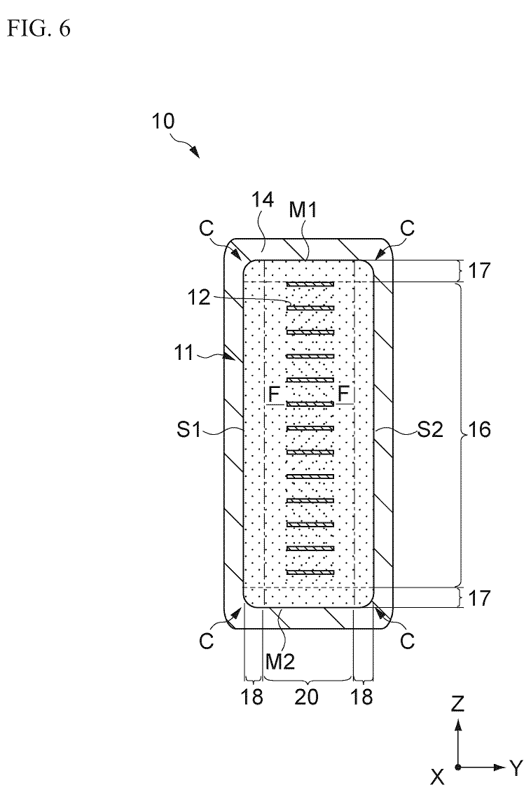

FIG. 4 illustrates the ceramic layers 19, one by one, on which the internal electrodes 12 and 13 are formed, respectively. FIG. 4 also illustrates the margin portions 18 adjacent to the ceramic layer 19. FIG. 5 is a vertical cross-sectional view of the multilayer ceramic capacitor 10 taken along line A2-A2′ in FIG. 1. FIG. 6 is a vertical cross-sectional view of the multilayer ceramic capacitor 10 taken along line B2-B2′ in FIG. 1. FIG. 5 and FIG. 6 illustrate cross sections of a section including the vicinities of the corner portions C of the ceramic body 11 in the multilayer ceramic capacitor 10.

As illustrated in FIG. 4, in each of the internal electrodes 12 and 13, the width dimension D1 in the Y-axis direction of the connection end En is smaller than the width dimension D2 in the Y-axis direction of the central in the X-axis direction. That is, each of the internal electrodes 12 and 13 has a planar shape that is narrowed inward from both sides in the Y-axis direction in the end portion in the X-axis direction including the connection end En. The center in the X-axis direction of each of the internal electrodes 12 and 13 is a position that bisects the opposing section in the X-axis direction.

In this configuration, the connection end En is separated from each of the margin portions 18, and the capacitance formation portion 16 includes electrode absence sections F, which are disposed between the connection ends En and the margin portions 18 and contain no electrode material. The electrode absence section F does not contain a low-melting-point metal or contains a low-melting-point metal at a concentration lower than that of the margin portion 18.

This reduces the amount of the low-melting-point metal distributed around the connection ends En, and inhibits the diffusion of Cu from the external electrodes 14 and 15 to the end portions including the connection ends En of the internal electrodes 12 and 13. Therefore, in the above-described configuration, the expansion of the end portions including the connection ends En of the internal electrodes 12 and 13 is inhibited while the insulation properties of the margin portions 18 are maintained by the low-melting-point metal. As a result, in the ceramic body 11, internal stress caused by expansion of the internal electrodes 12 and 13 is reduced, and thus, the generation of cracks in the corner portions C can be inhibited.

Further, as illustrated in FIG. 5 and FIG. 6, in the internal electrodes 12 and 13, the electrode absence sections F are provided, and thus the respective distances from the side surfaces S1 and S2 are larger in the end portion in the X-axis direction including the connection end En than in the center in the X-axis direction. In the ceramic body 11, the electrode absence sections F are provided in all the internal electrodes 12 and 13, and thus the internal electrodes 12 and 13 are not present near the four ridge portions along the Z-axis direction.

Thus, in the ceramic body 11, the corner portion C is less likely to be affected by the expansion of the internal electrodes 12 and 13. In the ceramic body 11, internal stress caused by expansion of the internal electrodes 12 and 13 is reduced near the four ridge portions. These also effectively inhibit the generation of cracks in the corner portions C in the ceramic body 11.

In the internal electrodes 12 and 13, as the dimension in the Y-axis direction of the electrode absence section F increases, the distance from the margin portion 18 increases, and thus, the generation of cracks in the ceramic body 11 can be more effectively inhibited. Therefore, in the internal electrodes 12 and 13, the width dimension D1 at the connection end En is preferably equal to or less than ⅘ of, more preferably equal to or less than ¾ of the width dimension D2 at the center in the X-axis direction.

On the other hand, in the internal electrodes 12 and 13, as the dimension in the Y-axis direction of the electrode absence section F decreases, the connection areas to the external electrodes 14 and 15 at the connection ends En increase, and thus, the occurrence of poor connection to the external electrodes 14 and 15 can be more effectively inhibited. Therefore, in the internal electrodes 12 and 13, the width dimension D1 at the connection end En is preferably equal to or greater than ½ of, more preferably equal to or greater than ⅔ of the width dimension D2 at the center in the X-axis direction.

As illustrated in FIG. 5, the electrode absence sections F between the margin portions 18 and the internal electrodes 12 preferably extend further in than the portions of the external electrode 14 extending to the main surfaces M1 and M2 in the X-axis direction, and the electrode absence sections F between the margin portions 18 and the internal electrodes 13 preferably extend further in than the portions of the external electrode 15 extending to the main surfaces M1 and M2 in the X-axis direction. This configuration can inhibit the generation of cracks in the portions of the ceramic body 11 covered with the external electrodes 14 and 15, which is difficult to visually inspect.

### [Method of Manufacturing Multilayer Ceramic Capacitor 10]

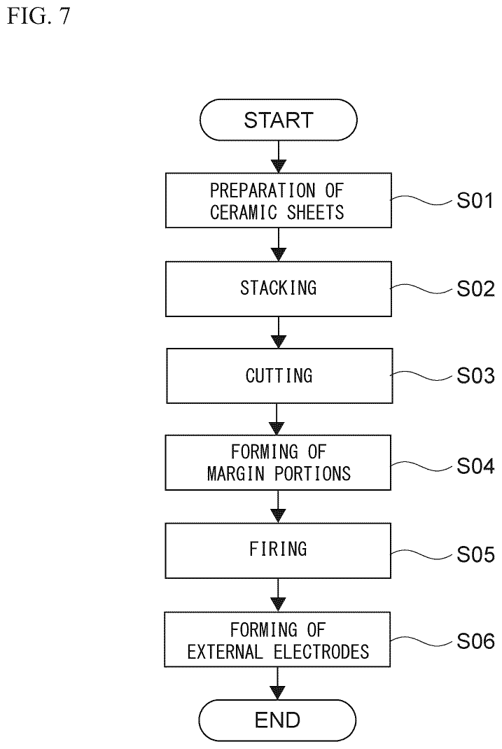

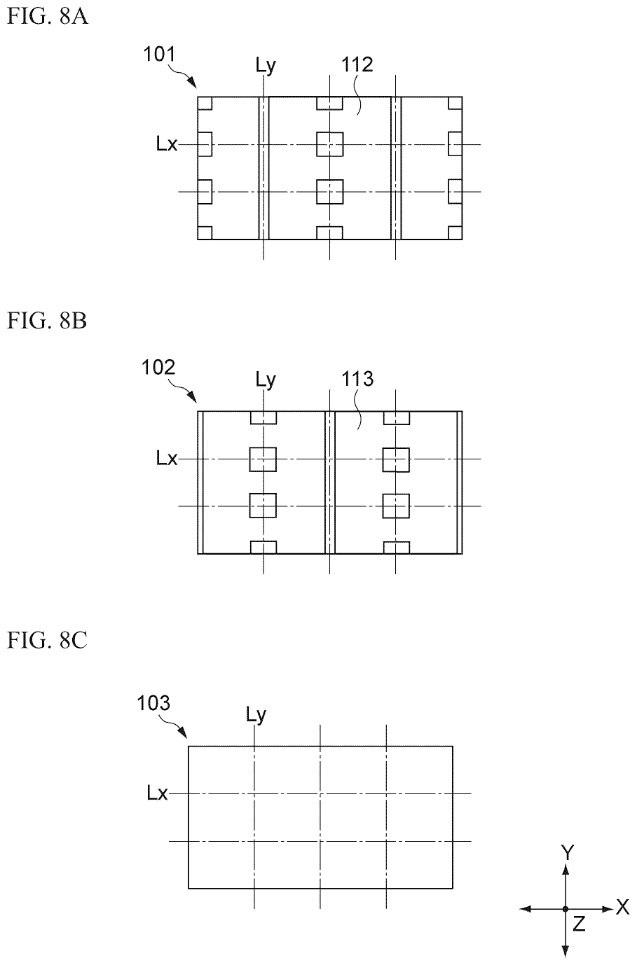

FIG. 7 is a flowchart illustrating a method of manufacturing the multilayer ceramic capacitor 10 according to the present embodiment. FIG. 8A to FIG. 12 illustrate a manufacturing process of the multilayer ceramic capacitor 10. Hereinafter, a method of manufacturing the multilayer ceramic capacitor 10 will be described with reference to these drawings as appropriate.

### (Step S01: Preparation of Ceramic Sheets)

In step S01, first and second ceramic sheets 101 and 102 for forming the capacitance formation portion 16 and third ceramic sheets 103 for forming the cover portions 17 are prepared. FIG. 8A, FIG. 8B, and FIG. 8C are plan views of the ceramic sheets 101, 102, and 103, respectively.

The ceramic sheets 101, 102, and 103 are all composed as unfired dielectric green sheets that are mainly composed of a dielectric ceramic. The material for the ceramic sheet contains, for example, ceramic powder, organic compounds such as a binder and an organic solvent, and other additives. The ceramic sheets 101, 102, and 103 are formed into a sheet shape by using, for example, a roll coater or a doctor blade.

In this stage, each of the ceramic sheets 101,102, and 103 is configured as a large-sized sheet that is not separated into individual pieces. In FIG. 8A, FIG. 8B, and FIG. 8C, first cut lines Lx parallel to the X-axis and second cut lines Ly parallel to the Y-axis are indicated by dash-dotted lines as cut lines for separating the multilayer ceramic capacitors 10 into individual pieces.

Unfired conductor patterns 112 and 113 corresponding to the internal electrodes 12 and 13 are formed on the ceramic sheets 101 and 102 constituting the capacitance formation portion 16, respectively. No unfired conductor patterns are formed on the third ceramic sheets 103 corresponding to the cover portions 17 where no internal electrodes are provided.

The conductor patterns 112 and 113 are formed by applying a conductive paste to the ceramic sheets 101 and 102, respectively. The method of applying the conductive paste can be freely selected from known techniques, and for example, a screen printing method or a gravure printing method can be used.

In each of the conductor patterns 112 and 113, spaces that are along the cut lines Ly and have a width in the X-axis direction are formed with one cut line Ly1 interposed therebetween. The spaces of the conductor pattern 112 and the spaces of the conductor pattern 113 are alternately arranged along the X-axis direction.

The conductor patterns 112 and 113 are formed continuously in the Y-axis direction. However, in each of the conductor patterns 112 and 113, regions that correspond to the electrode absence sections F and to which the conductive paste is not applied are provided.

### (Step S02: Stacking)

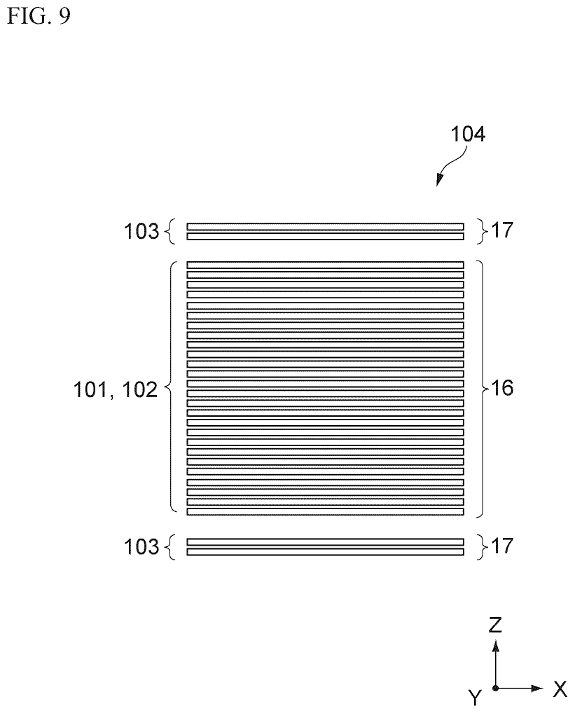

In step S02, the ceramic sheets 101, 102, and 103 prepared in step S01 are stacked as illustrated in FIG. 9 to produce a multilayer sheet 104. The multilayer sheet 104 is obtained by integrating the stacked ceramic sheets 101, 102, and 103 by hydrostatic pressurization, uniaxial pressurization, or the like.

In the multilayer sheet 104, the ceramic sheets 101 and 102 are alternately stacked in the Z-axis direction at positions corresponding to the capacitance formation portion 16. In the multilayer sheet 104, the third ceramic sheets 103 corresponding to the cover portions 17 are stacked on respective sides in the Z-axis direction of the stacked ceramic sheets 101 and 102.

### (Step S03: Cutting)

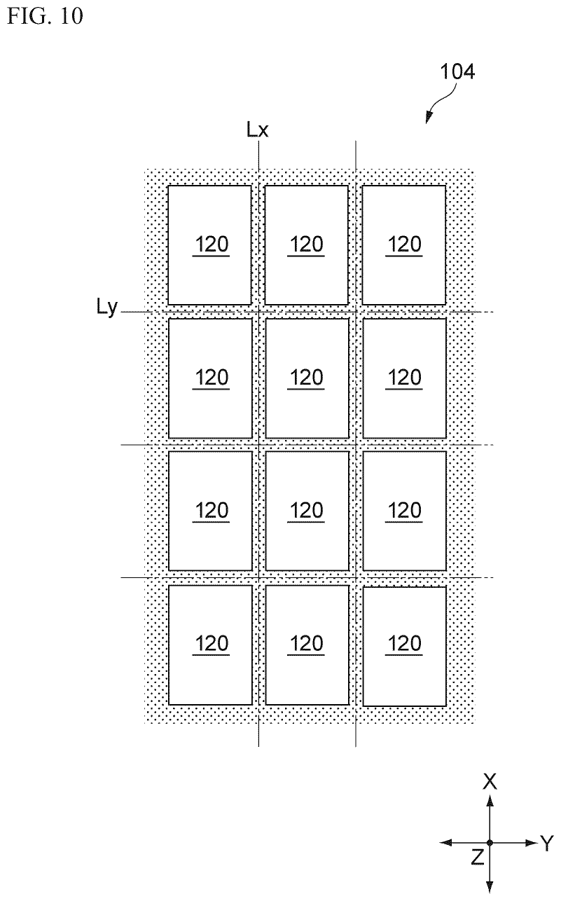

In step S03, the multilayer sheet 104 obtained in step S02 is cut along the cut lines Lx and Ly as illustrated in FIG. 10, thereby obtaining unfired multilayer chips 120 corresponding to the multilayer portions 20. For example, a cutting device provided with a push-cutting blade or a dicing device provided with a rotary blade can be used to cut the multilayer sheet 104 in step S03.

### (Step S04: Forming of Margin Portions)

In step S04, unfired margin portions 118 are formed on respective cut surfaces 120s perpendicular to the Y-axis of the multilayer chip 120 obtained in step S03. This produces an unfired ceramic body 11.

The margin portion 118 is formed by, for example, attaching a ceramic sheet or applying a ceramic slurry. The material for the margin portion 118 contains, for example, ceramic powder, the above-described low-melting-point metal, organic compounds such as a binder and an organic solvent, and other additives. The low-melting-point metal is added to the margin portion 118 so that the margin portion 118 has a higher concentration of the low-melting-point metal than the ceramic sheets 101, 102, and 103 of the multilayer chip 120.

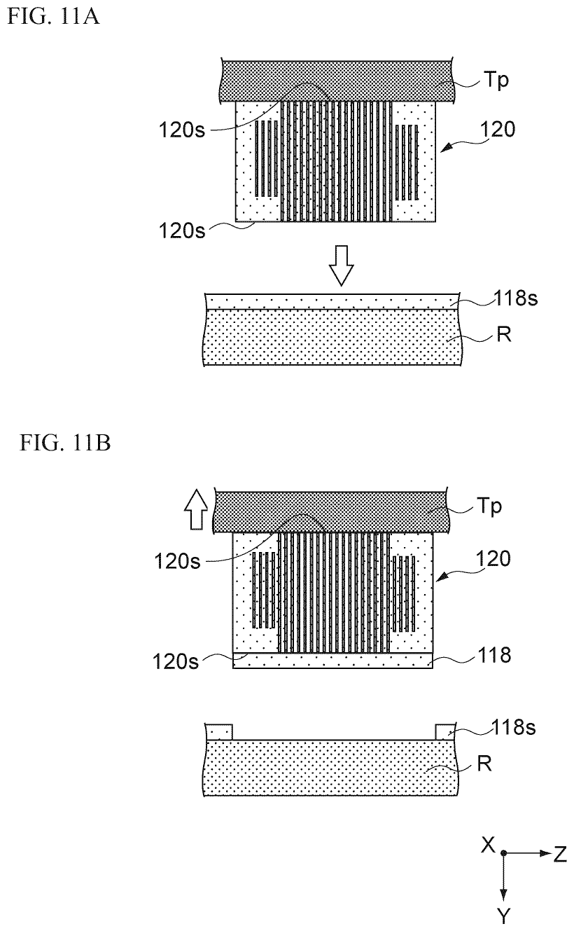

To form the margin portion 18 to have a uniform and small thickness, the margin portion 18 is preferably formed of a ceramic sheet. The following description will be made with reference to FIG. 11A and FIG. 11B.

As illustrated in FIG. 11A, first, one cut surface 120s of the multilayer chip 120 and a ceramic sheet 118s are opposed to each other. The ceramic sheet 118s is disposed on an elastic body R. The multilayer chip 120 is held by a tape Tp at the other cut surface 120s.

Then, as illustrated in FIG. 11A and FIG. 11B, the multilayer chip 120 is pressed against the ceramic sheet 118s in the Y-axis direction, and the ceramic sheet 118s is punched by the cut surface 120s of the multilayer chip 120. As a result, the ceramic sheet 118s punched along the peripheral edge of the cut surface 120s is attached to the cut surface 120s, and the unfired margin portion 118 is formed on the cut surface 120s.

Similarly, the ceramic sheet 118s is punched out on the other cut surface 120s of the multilayer chip 120, and another unfired margin portion 118 is formed on the other cut surface 120s. Through this process, the unfired ceramic body 11 including the multilayer chip 120 and a pair of the margin portions 118 is formed.

### (Step S05: Firing)

In step S05, the ceramic body 11 obtained in step S04 is fired. The firing temperature in step S05 can be set to about 1000 to 1300° C., for example, when a barium titanate (BaTiO₃)-based material is used. The firing can be performed, for example, in a reducing atmosphere or a low oxygen partial pressure atmosphere.

### (Step S06: Forming of External Electrodes)

In step S06, the multilayer ceramic capacitor 10 illustrated in FIG. 1 to FIG. 3 is produced by forming the external electrodes 14 and 15 on respective end portions in the X-axis direction of the ceramic body 11 obtained in step S05. The external electrodes 14 and 15 are formed by applying a conductive paste to the ceramic body 11 and firing the conductive paste.

In step S06, Cu in the conductive paste diffuses into the internal electrodes 12 and 13 while reacting with Ni constituting the internal electrodes 12 and 13. However, as described above, in the ceramic body 11, the connection ends En of the internal electrodes 12 and 13 are less likely to be affected by the low-melting-point metal, and thus, the diffusion of Cu near the connection ends En of the internal electrodes 12 and 13 is inhibited, and the generation of cracks is inhibited.

### [Mounting of Multilayer Ceramic Capacitor 10]

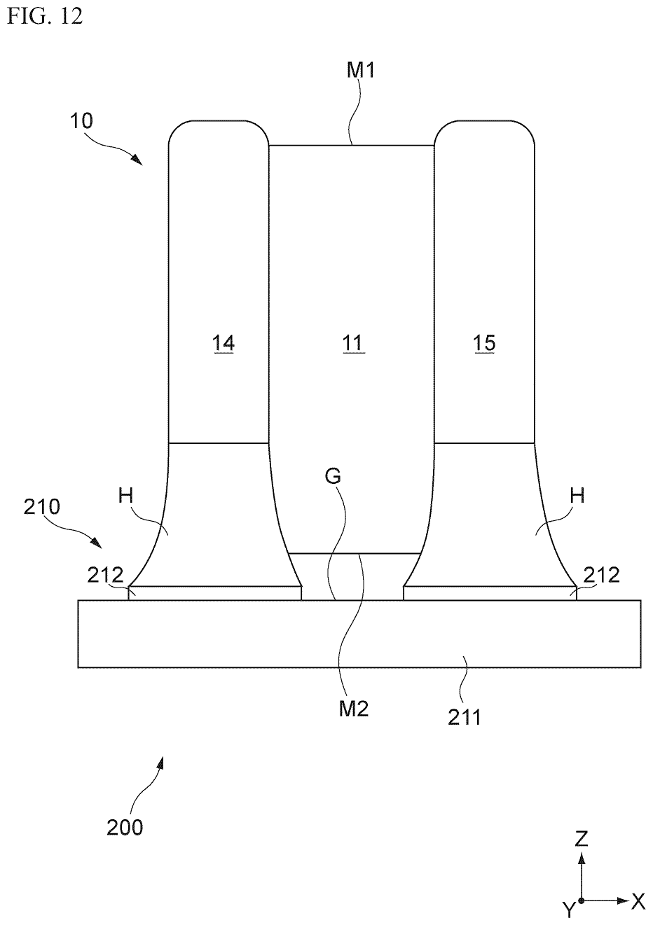

FIG. 12 is a side view of a circuit board 200 including the multilayer ceramic capacitor 10 according to the present embodiment. The circuit board 200 includes a mounting substrate 210 on which the multilayer ceramic capacitor 10 is mounted. The mounting substrate 210 includes a base material 211, which extends along the X-Y plane and has a mounting surface G perpendicular to the Z-axis, and a pair of connection electrodes 212 provided on the mounting surface G.

In the circuit board 200, the external electrodes 14 and 15 of the multilayer ceramic capacitor 10 are connected to the pair of connection electrodes 212 of the mounting substrate 210, respectively, with the solder H interposed therebetween. Accordingly, in the circuit board 200, the multilayer ceramic capacitor 10 is fixed to and electrically connected to the mounting substrate 210.

Here, in the multilayer ceramic capacitor 10, it is known that, when a voltage is applied to the external electrodes 14 and 15 through the connection electrodes 212 of the mounting substrate 210 at the time of driving the circuit board 200, electrostriction is generated in the ceramic body 11 due to the piezoelectric effect. The electrostriction generated in the ceramic body 11 causes relatively large deformation in the stacking direction of the internal electrodes 12 and 13.

In the circuit board 200, since electrostriction is repeatedly generated in the multilayer ceramic capacitor 10 to which an AC voltage is applied, and vibration in the thickness direction may be generated in the base material 211 of the mounting substrate 210. In the circuit board 200, when the vibration generated in the base material 211 increases, a phenomenon called “sound emission” in which noise sound is emitted from the base material 211 may occur.

In this regard, in the multilayer ceramic capacitor 10 according to the present embodiment, the electrode absence sections F are present on the outsides of the connection ends En in the Y-axis direction. Since the piezoelectric effect does not occur in the electrode absence sections F, the amount of deformation of the ceramic body 11 due to electrostriction is reduced by increasing the dimension in the X-axis direction of the electrode absence section F. Therefore, in the present embodiment, it is possible to inhibit sound emission in the circuit board 200.

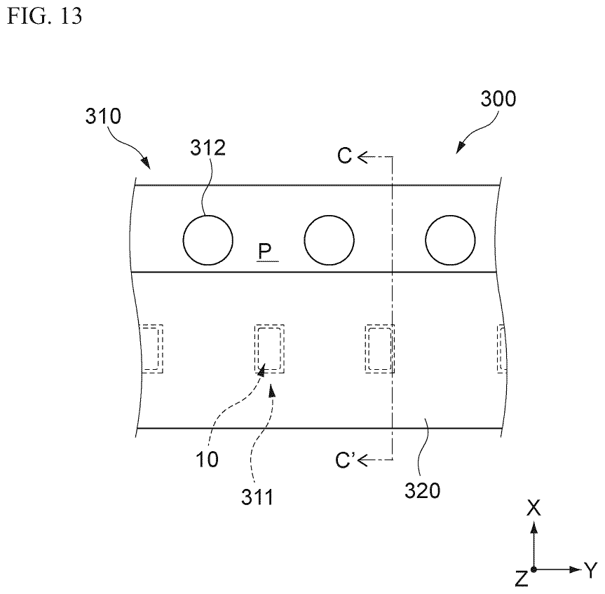

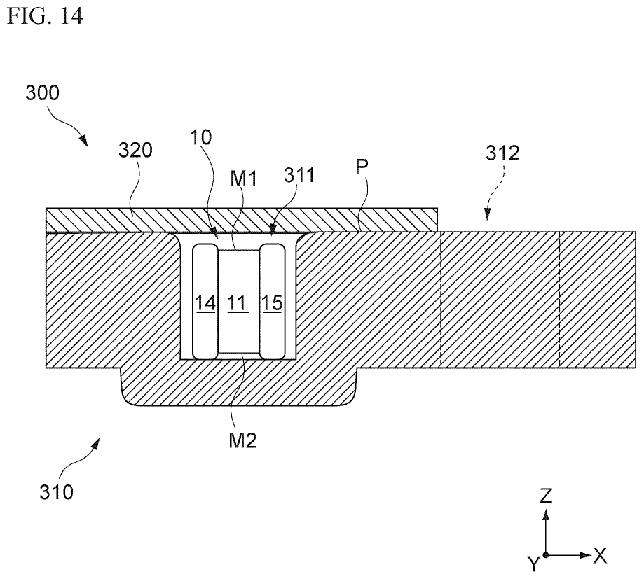

The multilayer ceramic capacitor 10 is prepared in a state of being packaged as a package 300 when being mounted on the mounting substrate 210. FIG. 13 and FIG. 14 illustrate the package 300. FIG. 13 is a partial plan view of the package 300. FIG. 14 is a cross-sectional view of the package 300 taken along line C-C′ in FIG. 13.

The package 300 includes the multilayer ceramic capacitor 10, a carrier tape 310, and a top tape 320. The carrier tape 310 is configured as a long tape extending in the Y-axis direction. In the carrier tape 310, a plurality of recesses 311 each accommodating one multilayer ceramic capacitor 10 are arranged at intervals in the Y-axis direction.

The carrier tape 310 has a sealing surface P, which is an upward surface orthogonal to the Z-axis, and the recesses 311 are recessed downward in the Z-axis direction from the sealing surface P. That is, the carrier tape 310 is configured so that the multilayer ceramic capacitors 10 in the recesses 311 can be taken out from the sealing surface P side.

In the carrier tape 310, a plurality of feed holes 312 penetrating through the carrier tape 310 in the Z-axis direction and arranged at intervals in the Y-axis direction are provided at positions shifted in the X-axis direction from the row of the recesses 311. The feed holes 312 are configured as engagement holes used for the tape transport mechanism to transport the carrier tape 310 in the Y-axis direction.

In the package 300, the top tape 320 is attached to the sealing surface P of the carrier tape 310 along the row of the recesses 311, and the recesses 311 accommodating the multilayer ceramic capacitors 10 are collectively covered with the top tape 320. Thus, the multilayer ceramic capacitors 10 are held in the recesses 311, respectively.

As illustrated in FIG. 14, in the multilayer ceramic capacitor 10 in the recess 311 of the carrier tape 310, the first main surface M1, which faces upward in the Z-axis direction, of the ceramic body 11 faces the top tape 320. The second main surface M2, which faces downward in the Z-axis direction, of the ceramic body 11 faces the bottom surface of the recess 311.

When the multilayer ceramic capacitor 10 packaged as the package 300 is mounted, the top tape 320 is peeled off from the sealing surface P of the carrier tape 310 along the Y-axis direction. Accordingly, in the package 300, the recesses 311 in which the multilayer ceramic capacitors 10 are accommodated, respectively, can be sequentially opened upward in the Z-axis direction.

The multilayer ceramic capacitor 10 accommodated in the opened recess 311 is taken out in a state where the first main surface M1, which faces upward in the Z-axis direction, of the ceramic body 11 is sucked by the tip of the suction nozzle of a mounting device. Then, the mounting device moves the suction nozzle to move the multilayer ceramic capacitor 10 onto the mounting surface G of the mounting substrate 210.

The mounting device releases the suction of the first main surface M1 of the ceramic body 11 by the suction nozzle in a state where the second main surface M2 of the ceramic body 11 is opposed to the mounting surface G, and the external electrodes 14 and 15 are aligned with the pair of connection electrodes 212 to which the solder paste is applied. This places the multilayer ceramic capacitor 10 on the mounting surface G.

Then, the solder paste is melted and then hardened by putting the mounting substrate 210 with the mounting surface G on which the multilayer ceramic capacitor 10 is placed into a reflow furnace or the like. Thus, the external electrodes 14 and 15 of the multilayer ceramic capacitor 10 are connected to the pair of connection electrodes 212 of the mounting substrate 210 through the solder H, and thus the circuit board 200 illustrated in FIG. 12 is obtained.

### Second Embodiment

The multilayer ceramic capacitor 10 according to a second embodiment of the present disclosure is different from the multilayer ceramic capacitor 10 according to the first embodiment only in the configuration of the internal electrodes 12 and 13, and has the appearance illustrated in FIG. 1, similarly to the multilayer ceramic capacitor 10 according to the first embodiment. In the present embodiment, the same or corresponding components as those in the first embodiment are denoted by the same reference numerals, and detailed description thereof will be omitted.

### [Structure of Multilayer Ceramic Capacitor 10]

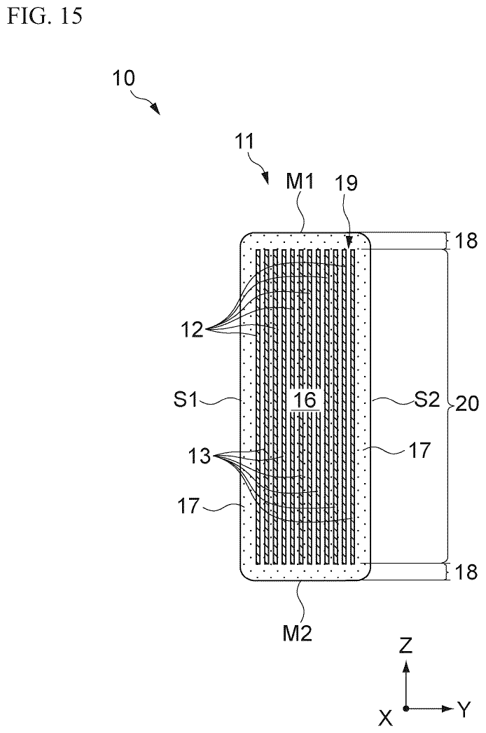

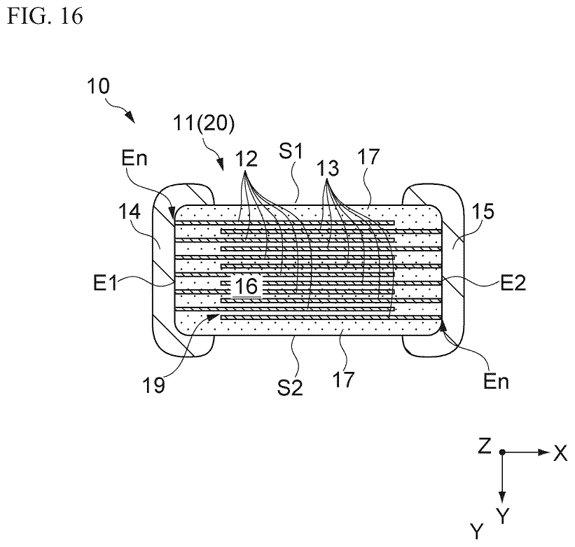

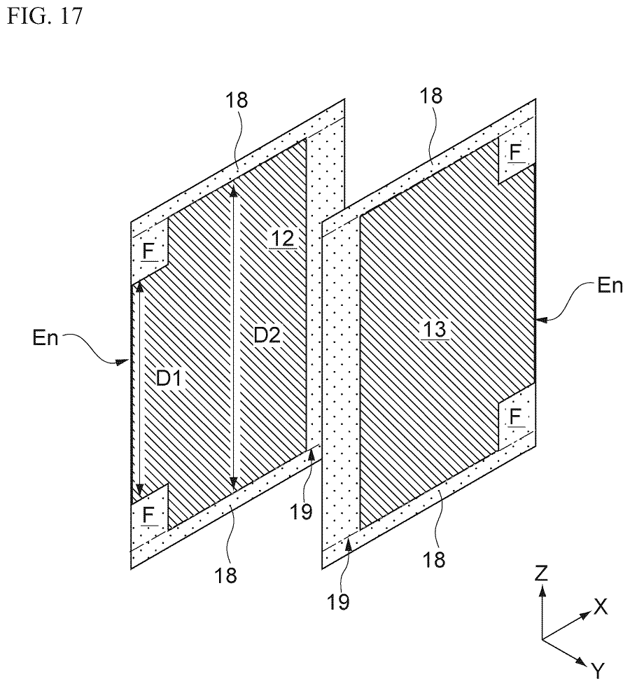

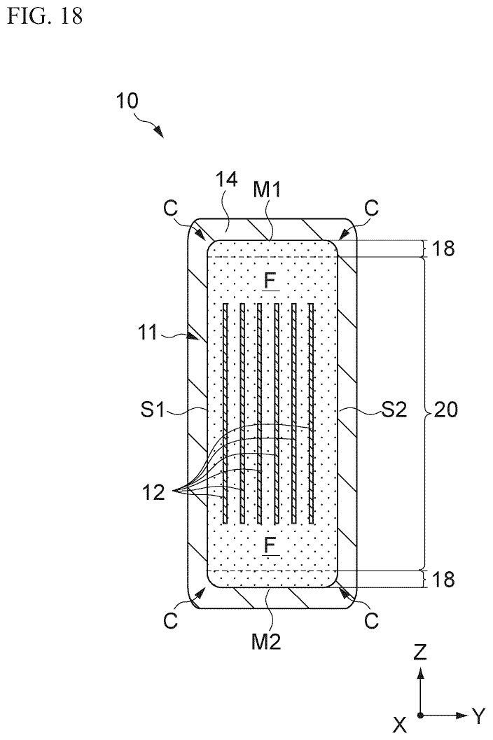

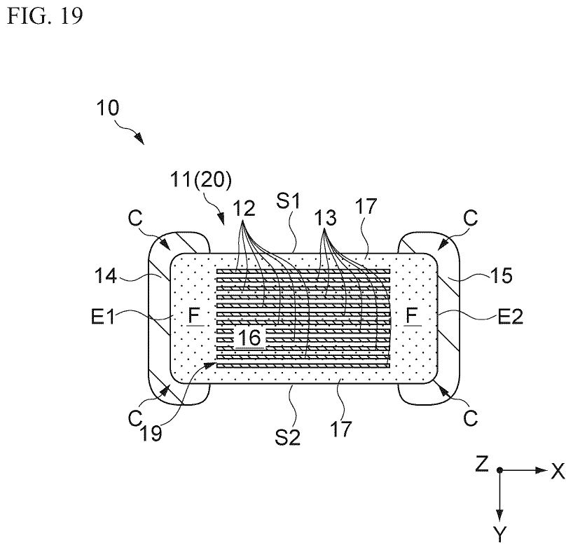

FIG. 15 to FIG. 19 illustrate the multilayer ceramic capacitor 10 according to the second embodiment of the present disclosure. FIG. 15 is a vertical cross-sectional view of the multilayer ceramic capacitor 10 taken along line B1-B1′ in FIG. 1. FIG. 16 is a horizontal cross-sectional view of the multilayer ceramic capacitor 10 taken along line D1-D1′ in FIG. 1. FIG. 17 is an exploded view partially illustrating the ceramic body 11 of the multilayer ceramic capacitor 10 for each ceramic layer 19. FIG. 18 is a vertical cross-sectional view of the multilayer ceramic capacitor 10 taken along line B2-B2′ in FIG. 1. FIG. 19 is a horizontal cross-sectional view of the multilayer ceramic capacitor 10 taken along line D2-D2′ in FIG. 1. FIG. 17 also illustrates the margin portions 18 adjacent to the ceramic layer 19.

In the capacitance formation portion 16 according to the first embodiment, the stacking direction of the internal electrodes 12 and 13 is parallel to the Z-axis, and the width direction of the internal electrodes 12 and 13 is parallel to the Y-axis. In contrast, in the capacitance formation portion 16 according to the present embodiment, the stacking direction is a direction parallel to the Y-axis, the lead-out direction of the internal electrodes 12 and 13 is a direction parallel to the X-axis, and the width direction of the internal electrodes 12 and 13 is a direction parallel to the Z-axis.

The internal electrodes 12 and 13 of the capacitance formation portion 16 are configured in a sheet shape extending along the X-Z plane, and are alternately stacked with the ceramic layers 19 in the Y-axis direction. In the present embodiment, the pair of cover portions 17 cover the capacitance formation portion 16 from the Y-axis direction.

In the present embodiment, the margin portions 18 are formed along the Y-axis direction and cover the multilayer portion 20 from the Z-axis direction. The margin portion 18 contains a low-melting-point metal having a melting point lower than that of Ni, which is the main component of the internal electrodes 12 and 13, as in the first embodiment.

As illustrated in FIG. 17, also in the present embodiment, in each of the internal electrodes 12 and 13, the width dimension D1 in the Z-axis direction at the connection end En is smaller than the width dimension D2 in the Z-axis direction at the center in the Z-axis direction. Thus, the connection end En of each of the internal electrodes 12 and 13 is separated from the margin portions 18, and the electrode absence sections F are disposed between the end portion including the connection end En and each of the margin portions 18 in each of the internal electrodes 12 and 13. Therefore, the distribution of the low-melting-point metal in the vicinity of the connection end En is inhibited, and the diffusion of Cu from the external electrodes 14 and 15 to the end portions including the connection ends En of the internal electrodes 12 and 13 is inhibited. As a result, in the ceramic body 11, internal stress caused by expansion of the internal electrodes 12 and 13 is reduced, and thus, the generation of cracks in the corner portions C can be inhibited.

In addition, in the present embodiment, since the stacking direction is parallel to the Y-axis, the total number of stacked internal electrodes 12 and 13 is smaller than that in the first embodiment in which the stacking direction is parallel to the Z-axis. Therefore, in the ceramic body 11, the amount of expansion of the internal electrodes 12 and 13 in the Y-axis direction due to diffusion of Cu contained in the external electrodes 14 and 15 can be reduced as a whole. Therefore, in the ceramic body 11, the internal stress caused by the expansion of the internal electrodes 12 and 13 can be kept small, and thus the generation of cracks can be inhibited.

Furthermore, in the present embodiment, since the width direction of the internal electrodes 12 and 13 is parallel to the Z-axis, the width dimension D1 along the Z-axis direction at the connection end En can be made larger than that in the first embodiment. Therefore, the areas of the connection ends En on the end surfaces E1 and E2 can be sufficiently secured. Thus, in the present embodiment, even when the width dimensions D1 at the connection ends En are smaller than the width dimensions D2 at the centers of the internal electrodes 12 and 13, poor connection between the internal electrode 12 and the external electrode 14 and between the internal electrode 13 and the external electrode 15 can be inhibited. As a result, according to the present embodiment, a decrease in the electrostatic capacitance of the multilayer ceramic capacitor 10 due to the poor connection can be reduced or prevented.

### [Method of Manufacturing Multilayer Ceramic Capacitor 10]

A method of manufacturing the multilayer ceramic capacitor 10 according to the present embodiment will be described below. The method of manufacturing the multilayer ceramic capacitor 10 according to the present embodiment is performed in accordance with the flowchart illustrated in FIG. 7. However, in the manufacturing method of the present embodiment, the planar shape of the conductor pattern, the number of stacked ceramic sheets, and the like are different from those of the first embodiment.

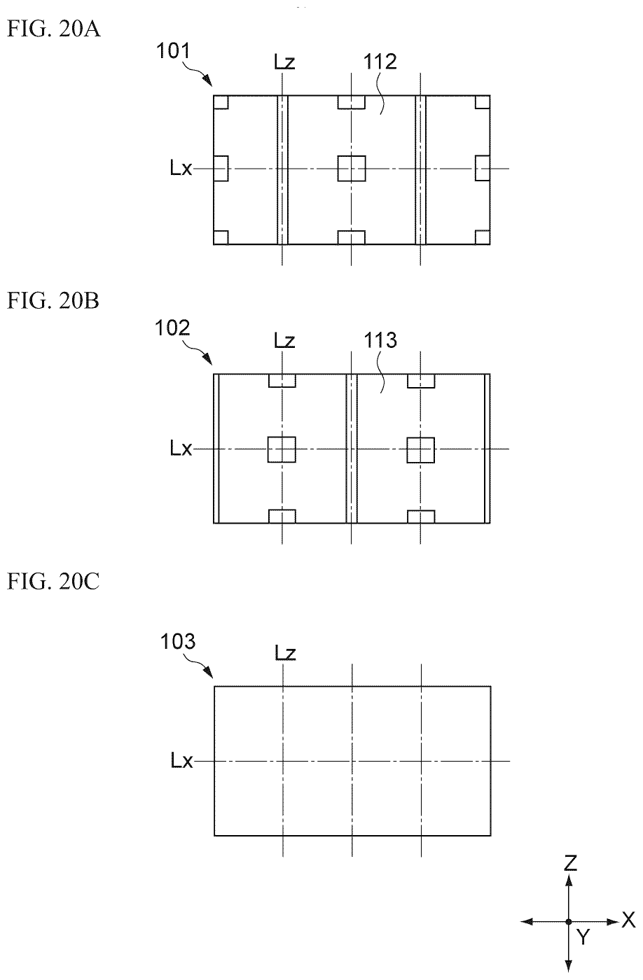

In step S01, as illustrated in the plan views of FIG. 20A, FIG. 20B, and FIG. 20C, the first and second ceramic sheets 101 and 102 for forming the capacitance formation portion 16 and the third ceramic sheets 103 for forming the cover portions 17 are prepared.

As illustrated in FIG. 20A, FIG. 20B, and FIG. 20C, the ceramic sheets 101, 102, and 103 according to the present embodiment extend along the X-Z plane, not the X-Y plane. Therefore, the ceramic sheets 101, 102, and 103 according to the present embodiment have a configuration in which the shapes of the ceramic sheets illustrated in FIG. 8A, FIG. 8B, and FIG. 8C are entirely extended in the Y-axis direction, and the Y-axis in FIG. 8A, FIG. 8B, and FIG. 8C is changed to the Z-axis. The cut lines for separating the multilayer ceramic capacitors 10 into individual pieces include the first cut lines Lx parallel to the X-axis and the second cut lines Lz parallel to the Z-axis.

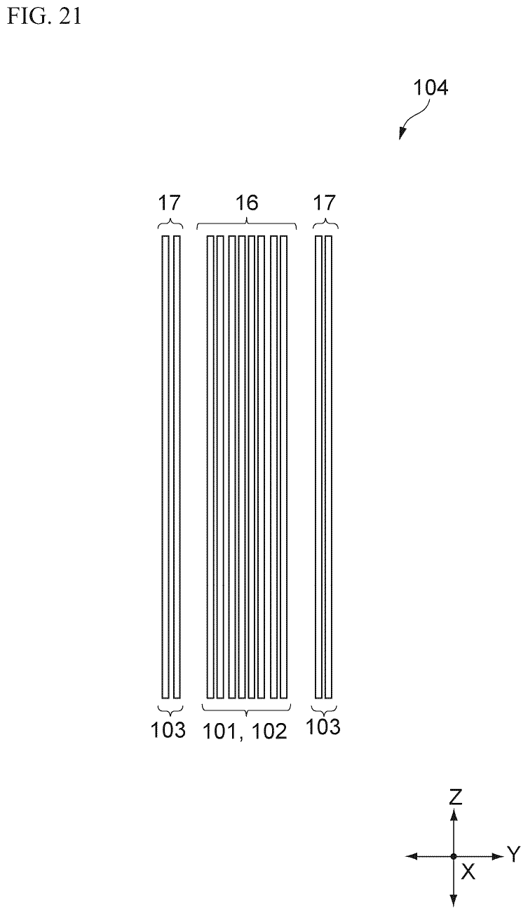

Then, in step S02, as illustrated in FIG. 21, the ceramic sheets 101, 102, and 103 are stacked and pressure-bonded in the Y-axis direction to produce the multilayer sheet 104. The number of stacked ceramic sheets 101, 102, and 103 is appropriately set according to the dimension of the ceramic body 11 in the Y-axis direction, and is typically set to be smaller than that in the first embodiment.

Then, in step S03, the multilayer sheet 104 obtained in step S02 is cut along the cut lines Lx and Lz, thereby obtaining the unfired multilayer chips 120.

Then, in step S04, the unfired margin portions 118 are formed on the respective cut surfaces 120s perpendicular to the Z-axis of the multilayer chip 120 obtained in step S03. Thus, the unfired ceramic body 11 is produced.

Then, step S05 (firing) similar to that of the first embodiment is performed, and the external electrodes 14 and 15 are formed on respective end portions in the X-axis direction of the ceramic body 11 in step S06 (forming of external electrodes) similar to that of the first embodiment, whereby the multilayer ceramic capacitor 10 illustrated in FIG. 15 to FIG. 19 is produced.

Here, in the ceramic body 11 of the present embodiment, since the stacking direction is parallel to the Y-axis, as described below, the main surfaces M1 and M2 can have higher flatness than the side surfaces S1 and S2.

The side surfaces S1 and S2 are formed by surfaces substantially perpendicular to the Y-axis of the multilayer sheet 104. As illustrated in FIG. 20A, FIG. 20B, and FIG. 20C, the ceramic sheets 101 and 102 have regions where no conductor patterns 112 and 113 are formed in parts. Therefore, steps and undulations due to the thicknesses of the conductor patterns 112 and 113 are likely to be formed on the surface substantially perpendicular to the Y-axis of the multilayer sheet 104, which is formed by stacking these ceramic sheets 101 and 102. That is, the flatness of the side surfaces S1 and S2 is likely to be low.

On the other hand, the main surfaces M1 and M2 are formed by the margin portions 18. In the present embodiment, the margin portion 18 is formed by attaching the ceramic sheet 118s to the cut surface 120s, which is substantially perpendicular to the Z-axis, of the multilayer chip 120. Since steps or undulations are not easily formed on the cut surface 120s or the ceramic sheet 118s, the main surfaces M1 and M2 can have higher flatness than the side surfaces S1 and S2.

As illustrated in FIG. 12, the main surfaces M1 and M2 face the mounting substrate 210 when the multilayer ceramic capacitor 10 is mounted on the mounting substrate 210. The high flatness of the main surfaces M1 and M2 can stabilize the posture of the multilayer ceramic capacitor 10 on the mounting substrate 210. Thus, the multilayer ceramic capacitor 10 is inhibited from tilting on the mounting substrate 210 even though it is a tall type with a high center of gravity. By inhibiting the tilt of the multilayer ceramic capacitor 10, contact between the multilayer ceramic capacitor 10 and an adjacent electronic component is inhibited, and thus, it is possible to inhibit a defect such as a short circuit.

Furthermore, since the main surfaces M1 and M2 have high flatness, as illustrated in FIG. 14, the multilayer ceramic capacitor 10 can be easily sucked from the package 300 including the multilayer ceramic capacitor 10, by a chip mounter for mounting.

If the first main surface M1 has a step or undulation, it is difficult for the suction nozzle of the chip mounter to stably suck the first main surface M1. In contrast, in the present embodiment, the main surfaces M1 and M2 have high flatness, and thus the suction nozzle can stably suck the first main surface M1. Therefore, in the multilayer ceramic capacitor 10, it is possible to effectively inhibit the poor suction at the time of mounting.

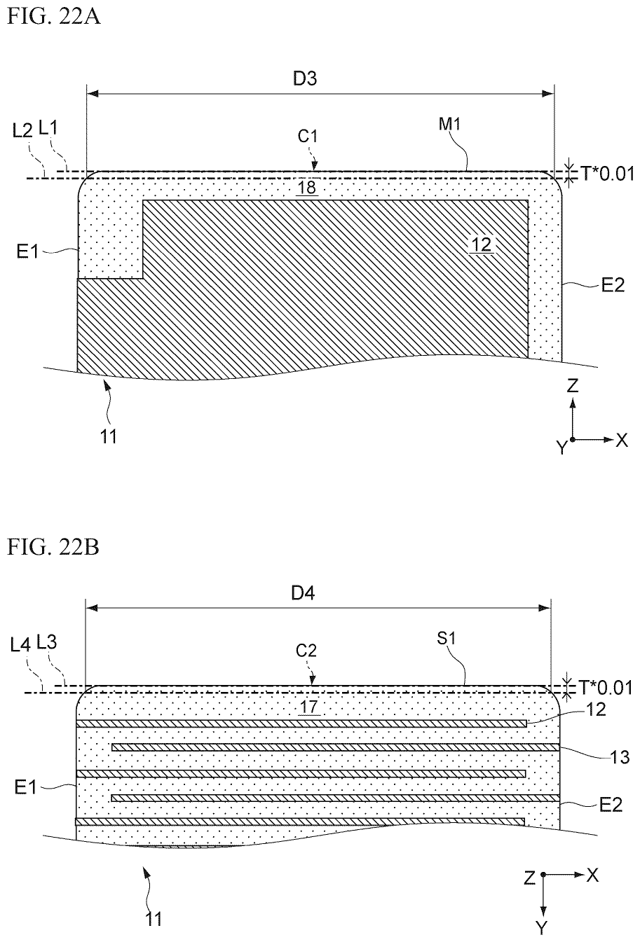

The flatness of each surface can be compared as follows. The cross-sectional view of FIG. 22A illustrates an example in which the first main surface M1 is the measurement target surface. The cross-sectional view of FIG. 22B illustrates an example in which the first side surface S1 is the measurement target surface.

First, as illustrated in FIG. 22A, a cross section perpendicular to the first main surface M1 and parallel to an X-Z plane that bisects the first main surface M1 is exposed. In this cross section, a first imaginary line L1, which passes through the center point C1 in the X-axis direction of the first main surface M1 and is parallel to the X-axis direction, and a second imaginary line L2, which is parallel to the first imaginary line L1 and is separated from the first imaginary line L1 by an interval of 1% of the dimension T in the Z-axis direction of the ceramic body 11 (T*0.01), are defined. Then, the distance between two points where the second imaginary line L2 and the first main surface M1 intersect is measured as a dimension D3 of the flat region of the first main surface M1. The dimension D3 of the second main surface M2 is also measured in the same manner.

As illustrated in FIG. 22B, a cross section perpendicular to the first side surface S1 and parallel to an X-Y plane that bisects the first side surface S1 is exposed. In this cross section, a third imaginary line L3, which passes through the center point C2 in the X-axis direction of the first side surface S1 and is parallel to the X-axis direction, and a fourth imaginary line L4, which is parallel to the third imaginary line L3 and is separated from the third imaginary line L3 by an interval of 1% of the dimension T in the Z-axis direction of the ceramic body 11 (T*0.01), are defined. Then, the distance between two points where the fourth imaginary line L4 and the first side surface S1 intersect is measured as a dimension D4 of the flat region of the first side surface S1. The dimension D4 of the second side surface S2 is also measured in the same manner.

Then, for five or more multilayer ceramic capacitors 10, the mean value of the dimensions D3 of the main surfaces M1 and M2 and the mean value of the dimensions D4 of the side surfaces S1 and S2 are calculated. The calculated mean value of the dimension D3 and the calculated mean value of the dimension D4 are compared, and when the mean value of the dimension D3 is larger than the mean value of the dimension D4, it can be determined that the main surfaces M1 and M2 have higher flatness than the side surfaces S1 and S2.

Furthermore, the multilayer ceramic capacitor 10 according to the present embodiment is able to effectively inhibit sound emission in the circuit board 200, as described below.

In the multilayer ceramic capacitor 10 according to the present embodiment, the stacking direction of the internal electrodes 12 and 13 is the in-plane direction of the base material 211, and thus vibration is less likely to be generated in the base material 211 due to the electrostriction of the ceramic body 11. In addition, the ceramic body 11 of the present embodiment has the electrode absent sections F as in the first embodiment, and the number of stacked internal electrodes 12 and 13 can be reduced. Therefore, in the present embodiment, the amount of deformation due to electrostriction in the ceramic body 11 can be further reduced, and sound emission in the circuit board 200 can be further effectively reduced.

### EXAMPLES

As Example 1 of the present disclosure, a sample of the multilayer ceramic capacitor 10 according to the first embodiment described above was fabricated. In addition, as Example 2 of the present disclosure, a sample of the multilayer ceramic capacitor 10 according to the second embodiment was fabricated. As Comparative Example of the present disclosure, a sample of a multilayer ceramic capacitor was fabricated in which the stacking direction of the internal electrodes 12 and 13 was parallel to the Z-axis and the width dimension of each of the internal electrodes 12 and 13 in the Y-axis direction was constant along the X-axis direction. One hundred samples were prepared for each of Examples 1 and 2 and Comparative Example.

As Example 3 of the present disclosure, a sample of the multilayer ceramic capacitor 10 according to the first embodiment described above was fabricated. In addition, as Example 4 of the present disclosure, a sample of the multilayer ceramic capacitor 10 according to the second embodiment described above was fabricated. One hundred samples were prepared for each of Examples 3 and 4.

In each of the samples of Examples 1 and 2 and Comparative Example, the dimension L in the X-axis direction was 0.6 mm, the dimension W in the Y-axis direction was 0.3 mm, and the dimension T in the Z-axis direction was 0.5 mm. In each of the samples of Examples 1 and 2 and Comparative Example, the thickness of each of the cover portions 17 was 25 μm, the thickness of each of the margin portions 18 was 25 μm, and the thickness of each of the internal electrodes 12 and 13 and the ceramic layers 19 was 0.5 μm.

In each of the samples of Examples 3 and 4, the dimension L in the X-axis direction was 0.6 mm, the dimension W in the Y-axis direction was 0.3 mm, and the dimension T in the Z-axis direction was 0.4 mm. In each of the samples of Examples 3 and 4, the thickness of each of the cover portions 17 was 25 μm, the thickness of each of the margin portions 18 was 25 μm, and the thickness of each of the internal electrodes 12 and 13 and the ceramic layers 19 was 0.5 μm.

In the internal electrodes 12 and 13 of the samples of Example 1, the width dimension D2 at the center in the X-axis direction was 0.25 mm, the width dimension D1 at the connection end En was 0.15 mm, and the dimension in the X-axis direction of the end portion (electrode absence section F) including the connection end En was 25 μm. In the samples of Example 1, the total number of stacked internal electrodes 12 and 13 was 450.

In the internal electrodes 12 and 13 of the samples of Example 2, the width dimension D2 at the center in the X-axis direction was 0.45 mm, the width dimension D1 at the connection end En was 0.30 mm, and the dimension in the X-axis direction of the end portion (electrode absence section F) including the connection end En was 25 μm. In the samples of Example 2, the total number of stacked internal electrodes 12 and 13 was 250.

In the samples of Comparative Example, the width dimensions of the internal electrodes 12 and 13 was 0.25 mm, and the total number of the stacked internal electrodes 12 and 13 was 450.

In the internal electrodes 12 and 13 of the samples of Example 3, the width dimension D2 at the center in the X-axis direction was 0.25 mm, the width dimension D1 at the connection end En was 0.15 mm, and the dimension in the X-axis direction of the end portion (electrode absence section F) including the connection end En was 25 μm. In the samples of Example 3, the total number of stacked internal electrodes 12 and 13 was 350.

In the internal electrodes 12 and 13 of the samples of Example 4, the width dimension D2 at the center in the X-axis direction was 0.35 mm, the width dimension D1 at the connection end En was 0.25 mm, and the dimension in the X-axis direction of the end portion (electrode absence section F) including the connection end En was 25 μm. In the samples of Example 2, the total number of stacked internal electrodes 12 and 13 was 250.

In the samples of Examples 1 and 2 and Comparative Example, a low-melting-point metal having a melting point lower than that of Ni was added to the ceramic sheets 118s constituting the margin portions 18. No low-melting-point metal was added to the ceramic sheets 101, 102, and 103 constituting the multilayer portion 20.

In the samples of Examples 3 and 4, a low-melting-point metal having a melting point lower than that of Ni was added to the ceramic sheets 118s constituting the margin portions 18. No low-melting-point metal was added to the ceramic sheets 101, 102, and 103 constituting the multilayer portion 20.

For each of Examples 1 and 2 and Comparative Example, 100 samples were fabricated, and the internal cross sections of the respective portions covered with the external electrodes 14 and 15 was observed. As a result, no crack was observed in the samples of Examples 1 and 2. On the other hand, in the samples of Comparative Example, a crack was observed in at least one of the corner portions C. Thus, it was found that the samples of Examples 1 and 2 can inhibit the generation of cracks as compared with the samples of Comparative Example.

For each of Examples 3 and 4, 100 samples were fabricated, and the internal cross sections of the respective portions covered with the external electrodes 14 and 15 were observed. As a result, no crack was observed in the samples of Examples 3 and 4. Thus, it was found that the samples of Examples 3 and 4 were able to inhibit the generation of cracks as compared with the samples of Comparative Example.

The samples of Examples 1 and 2 and Comparative Example were subjected to a reliability test in which a direct current voltage of 10 V was applied under an environment of 105° C. Some of the samples of Comparative Example reached dielectric breakdown in less than 500 hours, but no sample of Examples 1 and 2 reached dielectric breakdown in less than 500 hours. Thus, it was found that the samples of Examples 1 and 2 can inhibit the poor insulation more than the samples of Comparative Example.

The samples of Examples 3 and 4 were subjected to a reliability test in which a direct current voltage of 10 V was applied in an environment of 105° C. In the samples of Examples 3 and 4, no sample reached dielectric breakdown in less than 500 hours. Thus, it was found that the samples of Examples 3 and 4 were able to inhibit poor insulation more than the samples of Comparative Example.

Further, the electrostatic capacitance was measured under the conditions of 1 KHz and 0.5 Vrms for 100 samples of each of Examples 1 and 2. Then, for each of Examples 1 and 2, the largest value and the smallest value with respect to the average value of the electrostatic capacitance were calculated, and it was confirmed whether the largest value and the smallest value were within a range of +5% centered on the average value. In Example 2, the largest value and the smallest value of the electrostatic capacitance were within a range of +5% centered on the average value. On the other hand, in Example 1, the largest value and the smallest value of the electrostatic capacitance were out of the range of +5% centered on the average value.

From this result, it was found that the samples of Example 2 can reduce the variation in electrostatic capacitance more than the samples of Example 1. The reason for this is presumed to be that poor connection between the external electrode 14 and the internal electrode 12 and poor connection between the external electrode 15 and the internal electrode 13 are inhibited in the samples of Example 2.

The electrostatic capacitance was measured under the conditions of 1 kHz and 0.5 Vrms for 100 samples of each of Examples 3 and 4. Then, for each of Examples 3 and 4, the largest value and the smallest value with respect to the average value of the electrostatic capacitance were calculated, and it was confirmed whether the largest value and the smallest value were within a range of +5% centered on the average value. In Example 4, the largest value and the smallest value of the electrostatic capacitance were within a range of +5% centered on the average value. On the other hand, in Example 3, the largest value and the smallest value of the electrostatic capacitance were out of range of +5% centered on the average value.

This result reveals that the samples of Example 4 can reduce the variation in electrostatic capacitance more than the samples of Example 3. The reason for this is presumed to be that in the samples of Example 4, poor connection between the external electrode 14 and the internal electrode 12 and poor connection between the external electrode 15 and the internal electrode 13 were inhibited.

Factors that greatly affect the occurrence of poor connection between the external electrode 14 and the internal electrode 12 and between the external electrode 15 and the internal electrode 13 include the areas of the connection ends En of the internal electrodes 12 and 13 on the end surfaces E1 and E2. For example, in the internal electrodes 12 and 13 of the second embodiment, the thickness is 0.5 μm, and the width dimension of the connection end En is 300 μm, and therefore, the area obtained by multiplying these values is 150 μm². On the other hand, in the internal electrodes 12 and 13 of the first embodiment, the thickness is 0.5 μm, and the width dimension of the connection end En is 150 μm, and therefore, the area obtained by multiplying these values is 75 μm².

As described above, in the samples of Example 2, the areas of the connection ends En of the internal electrodes 12 and 13 exposed on the end surfaces E1 and E2, respectively are two times those in the samples of Example 1, and the connection ends En are likely to be stably connected to the external electrodes 14 and 15. As a result, it is presumed that the variation in electrostatic capacitance was reduced in the samples of Example 2 as compared in the samples of Example 1.

In the internal electrodes 12 and 13 of Example 4, the thickness is 0.5 μm, and the width dimension of the connection end En is 250 μm, and therefore, the area obtained by multiplying these values is 125 μm². On the other hand, in the internal electrodes 12 and 13 of Example 3, the thickness is 0.5 μm, and the width dimension of the connection end En is 150 μm, and therefore, the area is 75 μm² obtained by multiplying these values.

As described above, in the samples of Example 4, the areas of the connection ends En of the internal electrodes 12 and 13 exposed on the end surfaces E1 and E2, respectively, are 1.6 times those in the samples of Example 3, and the connection ends En are likely to be stably connected to the external electrodes 14 and 15. As a result, it is presumed that the variation in electrostatic capacitance was reduced in the samples of Example 4 as compared in the samples of Example 3.

### OTHER EMBODIMENTS

Although the embodiments of the present invention have been described above, the present invention is not limited to the above-described embodiments, and various modifications can be made.

For example, the shapes of the electrode absence sections F in the internal electrodes 12 and 13 can be changed within a range in which the effect of the present disclosure is exhibited. For example, the electrode absence sections F of the internal electrodes 12 and 13 may have an outline form including a curve. Between the internal electrodes 12 and 13, the shapes of the electrode absence sections F may be different.

Furthermore, in the multilayer ceramic capacitor 10, the first main surface M1 and the second main surface M2 of the ceramic body 11 may be reversed. That is, in the circuit board 200 illustrated in FIG. 12 and the ceramic body 11 of the multilayer ceramic capacitor 10 in the package 300 illustrated in FIG. 14, the first main surface M1 may face downward in the Z-axis direction and the second main surface M2 may face upward in the Z-axis direction.

What is claimed is:

1. A multilayer ceramic capacitor that has a dimension in a first direction along a first axis equal to or greater than 1.5 times a dimension in a second direction along a second axis orthogonal to the first axis, and is to be mounted on a mounting surface perpendicular to the first axis, the multilayer ceramic capacitor comprising:
a ceramic body having a pair of main surfaces perpendicular to the first axis, a pair of side surfaces perpendicular to the second axis, and a pair of end surfaces perpendicular to a third axis orthogonal to the first axis and the second axis; and
a pair of external electrodes that contain Cu as a main component and cover the pair of end surfaces, respectively,
wherein the ceramic body further includes:
a multilayer portion including a plurality of internal electrodes that contain Ni as a main component, are alternately stacked with ceramic layers along a stacking direction parallel to the first axis or the second axis, and are led out to connection ends on the end surfaces, respectively, and
a pair of margin portions that are formed along the stacking direction, cover the multilayer portion from a width direction of the internal electrodes, and contain a low-melting-point metal having a melting point lower than that of Ni, the width direction being orthogonal to the stacking direction and the third axis,
wherein in each of the internal electrodes, a width dimension in the width direction is smaller at the connection end than at a center in a third direction along the third axis.

2. The multilayer ceramic capacitor according to claim 1, wherein the low-melting-point metal is at least one of the following metals: Sn, Zn, Al, Ga, Ge, and Ag.

3. The multilayer ceramic capacitor according to claim 1, wherein the width dimension at the connection end is equal to or greater than ½ of and equal to or less than ¾ of the width dimension at the center.

4. The multilayer ceramic capacitor according to claim 1,
wherein the stacking direction is parallel to the second axis, and
wherein the width direction of each of the internal electrodes is parallel to the first axis.

5. The multilayer ceramic capacitor according to claim 4, wherein the pair of main surfaces have higher flatness than the pair of side surfaces.

6. A package comprising:
the multilayer ceramic capacitor according to claim 1;
a carrier tape having a sealing surface perpendicular to the first axis, and a recess that is recessed from the sealing surface in the first direction and accommodates the multilayer ceramic capacitor; and
a top tape that is attached to the sealing surface and covers the recess.

7. A circuit board comprising:
the multilayer ceramic capacitor according to claim 1; and
a mounting substrate having the mounting surface, and a pair of connection electrodes that are provided on the mounting surface and connected to the pair of external electrodes of the multilayer ceramic capacitor through solder, respectively.

8. A multilayer ceramic capacitor that has a dimension in a first direction along a first axis equal to or greater than 1.3 times a dimension in a second direction along a second axis orthogonal to the first axis, and is to be mounted on a mounting surface perpendicular to the first axis, the multilayer ceramic capacitor comprising:
a ceramic body having a pair of main surfaces perpendicular to the first axis, a pair of side surfaces perpendicular to the second axis, and a pair of end surfaces perpendicular to a third axis orthogonal to the first axis and the second axis; and
a pair of external electrodes that contain Cu as a main component and cover the pair of end surfaces, respectively,
wherein the ceramic body further includes:
a multilayer portion including a plurality of internal electrodes that contain Ni as a main component, are alternately stacked with ceramic layers along a stacking direction parallel to the first axis or the second axis, and are led out to connection ends on the end surfaces, respectively; and
a pair of margin portions that are formed along the stacking direction, cover the multilayer portion from a width direction of the internal electrodes, and contain a low-melting-point metal having a melting point lower than that of Ni, the width direction being orthogonal to the stacking direction and the third axis,
wherein in each of the internal electrodes, a width dimension in the width direction is smaller at the connection end than at a center in a third direction along the third axis.

9. The multilayer ceramic capacitor according to claim 8, wherein the low-melting-point metal is at least one of the following metals: Sn, Zn, Al, Ga, Ge, and Ag.

10. The multilayer ceramic capacitor according to claim 8, wherein the width dimension at the connection end is equal to or greater than ½ of and equal to or less than ¾ of the width dimension at the center.

11. The multilayer ceramic capacitor according to claim 8,
wherein the stacking direction is parallel to the second axis, and
wherein the width direction of the internal electrode is parallel to the first axis.

12. The multilayer ceramic capacitor according to claim 11, wherein the pair of main surfaces have higher flatness than the pair of side surfaces.

13. A package comprising:
the multilayer ceramic capacitor according to claim 8;
a carrier tape having a sealing surface perpendicular to the first axis, and a recess that is recessed from the sealing surface in the first direction and accommodates the multilayer ceramic capacitor; and
a top tape that is attached to the sealing surface and covers the recess.

14. A circuit board comprising:
the multilayer ceramic capacitor according to claim 8; and
a mounting substrate having the mounting surface, and a pair of connection electrodes provided on the mounting surface and connected to the pair of external electrodes of the multilayer ceramic capacitor through solder, respectively.
